(19) United States
(12) Patent Application Publication
(10) Pub. No.: US 2022/0099380 A1
(43) Pub. Date: Mar. 31, 2022

(54) ENCLOSED HEAT SINK WITH BRAZED STRUCTURE

(71) Applicant: AMULAIRE THERMAL TECHNOLOGY, INC., New Taipei City (TW)

(72) Inventors: CHING-MING YANG, New Taipei City (TW); REUI-JEN YANG, New Taipei City (TW); TZE-YANG YEH, New Taipei City (TW)

(21) Appl. No.: 17/033,941

(22) Filed: Sep. 28, 2020

(51) Int. Cl. F28D 9/00; F28F 3/04

(52) U.S. Cl. CPC F28D 9/0031; F28F 2275/04; F28F 3/046

(57) ABSTRACT

An enclosed heat sink with a brazed structure is provided. The enclosed heat sink with the brazed structure includes a first brazing plane formed on a top surface of a first brazing body, and a second brazing plane formed on a bottom surface of a second brazing body. The first brazing plane and the second brazing plane are pressed and brazed together, so that the first brazing body and the second brazing body enclose a cavity. A plurality of channels are formed on the first brazing plane, and each of the channels is neither perpendicular nor parallel to the first brazing plane.

### FIELD OF THE DISCLOSURE

The present disclosure relates to an enclosed heat sink, and more particularly to an enclosed heat sink with a brazed structure.

### BACKGROUND OF THE DISCLOSURE

Heat sinks are commonly used in relevant industries for various products. In general, a liquid cooling heat sink is often used in higher-end products, and has the advantages of being quieter and more stable in cooling down than an air cooling heat sink. In addition, the liquid cooling heat sink is formed through an upper and lower workpiece being brazed together to form an enclosed space that is filled with a working fluid.

However, during a process of brazing and applying a brazing material, melted brazing materials often produce residues such as bubbles, slag inclusions, flux, etc. Moreover, when the structure of a brazing workpiece is very complex, a preset brazing material is placed between the upper and lower workpieces, so that pressure is applied to the upper and lower workpieces, which are pressed against each other during the brazing process. This results in a difficulty for impurities of the workpieces to be discharged from the brazing planes, such that large amount of voids can be formed from poor brazing techniques, especially in brazing workpieces where flux are applied.

### SUMMARY OF THE DISCLOSURE

In response to the above-referenced technical inadequacies, the present disclosure provides an enclosed heat sink, and more particularly an enclosed heat sink with a brazed structure.

In one aspect, the present disclosure provides an enclosed heat sink with a brazed structure. The enclosed heat sink includes a first brazing plane that is formed by a top surface of a first brazing body, and a second brazing plane that is formed by a bottom surface of a second brazing body. The first brazing plane and the second brazing plane are pressed and brazed together, so that the first brazing body and the second brazing body enclose a cavity. A plurality of channels are formed on the first brazing plane, and each of the channels is neither perpendicular nor parallel to the first brazing plane.

In a preferred embodiment, a plurality of channels are formed on the second brazing plane, and each of the channels on the second brazing plane is neither perpendicular nor parallel to the second brazing plane.

In a preferred embodiment, the channels are surface finishing line structures that are formed in a diagonal direction in a surface finishing manner.

In a preferred embodiment, the channels are cut out using hand tools, carved out using sandpaper, or cut out using a computer numerical control machine.

In a preferred embodiment, the first brazing body is a box-shaped body, and the second brazing body is a cover body.

In a preferred embodiment, the first brazing body has the box-shaped body that is surrounded by a plurality of surface walls, and the first brazing plane is jointly formed by top surfaces of the surface walls.

In a preferred embodiment, the channels are surface finishing line structures formed in a diagonal direction in a surface finishing manner, and a surface finishing line angle between the surface finishing line structure and a long side of each of the surfaces walls is 45 degrees.

In a preferred embodiment, a surface finishing line structure is formed by the channels, such that a surface roughness Ra of the first brazing plane is from 3.2 to 6.4 μm.

A beneficial effect of the present disclosure is that the enclosed heat sink with the brazed structure of the present disclosure reduces a pressured area of the structure by forming the channels through the brazing planes, and through a diagonal arrangement of each the channels. The structure is neither perpendicular nor parallel to the brazing planes, which increases the possibility of gas and flux to be discharged, and reduce amounts of voids produced during the brazing process, so as to effectively improve the quality of brazing.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a schematic view of an enclosed heat sink with a brazed structure of the present disclosure.

FIG. 2 is a top schematic view of a first brazing body of the enclosed heat sink with the brazed structure of the present disclosure.

FIG. 3 is a front schematic view taken along line III-III of FIG. 2.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

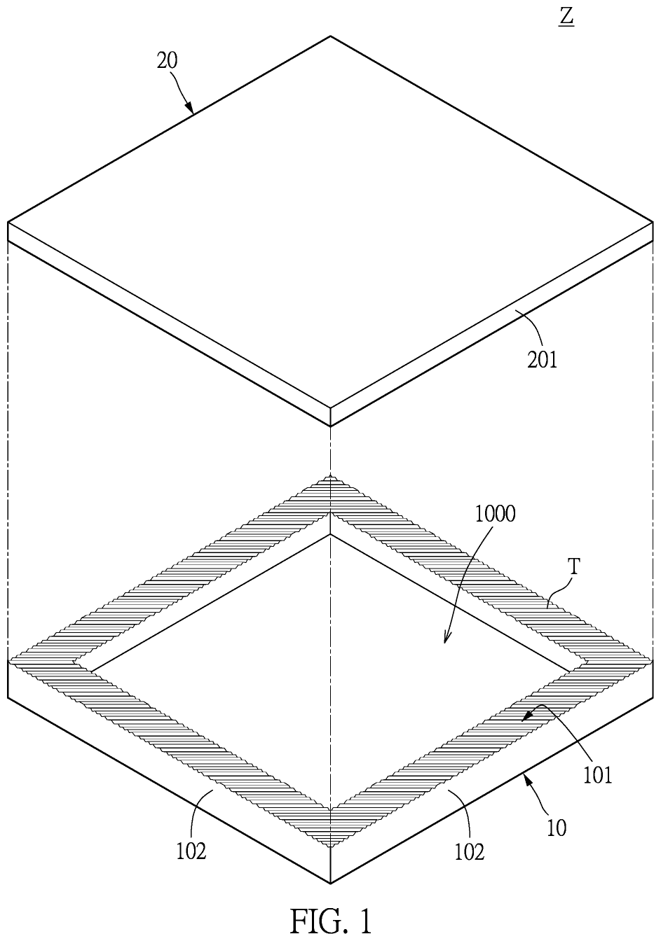

Referring to FIG. 1 to FIG. 3, the embodiment of the present disclosure provides an enclosed heat sink with a brazed structure. The enclosed heat sink Z is, for example, a liquid cooling heat sink that can have a cavity 1000, and the cavity 1000 can be filled with an appropriate amount of working fluid. In addition, a plurality of channels, an array of fins, or an array of columns can also be disposed inside the cavity 1000, and can be appropriately adjusted according to practical requirements, and it is not limited thereto.

According to the enclosed heat sink with the brazed structure provided by the embodiment of the present disclosure, a standard heat sink includes a first brazing body 10 and a second brazing body 20, and the first brazing body 10 and the second brazing body 20 surrounds the cavity 1000.

In addition, a first brazing plane 101 is formed by a top surface of the first brazing body 10, and a second brazing plane 201 is formed by a bottom surface of the second brazing body 20. The first brazing plane 101 of the first brazing body 10 and the second brazing plane 201 of the second brazing body 20 are pressed and brazed together.

Furthermore, the first brazing plane 101 and the second brazing plane 201 are preferably pressed and brazed together through a preset brazing material, so that the first brazing plane 101 and the second brazing plane 201 are pressed and brazed together into a one-piece structure. Specifically speaking, the brazing material can be in forms of a brazing rod, a brazing sheet, a brazing paste, composite materials, etc. Also, the shape and size of the brazing material can be appropriately adjusted according to the size of the first brazing plane 101 or the second brazing plane 201. The brazing material can also be brazing preforms that are coated with flux. In addition, the first brazing plane 101 and the second brazing plane 201 can also be coated with the flux if necessary, but the present embodiment is not limited thereto.

In the present embodiment, the first brazing body 10 can be a box-shaped body, and the second brazing body 20 can be a cover body. In other embodiments, the first brazing body 10 can be the cover body, and the second brazing body 20 can be the box-shaped body. The first brazing body 10 can be the box-shaped body that is surrounded by four of the surface walls 102, and the first brazing plane 101 can be jointly formed by top surfaces of four of the surface walls 102.

In other embodiments, the first brazing body 10 can have the box-shaped body that is surrounded by six of the surface walls 102, as well as having the box-shaped body that is surrounded by eight of the surface walls 102, so that the first brazing plane 101 can be jointly formed by top surfaces of either six of the surface walls 102 or eight of the surface walls 102.

Furthermore, a plurality of channels T are formed on the first brazing plane 101 of the first brazing body 10, and each of the channels T is disposed diagonally, and neither perpendicular nor parallel to the first brazing plane 101. Therefore, in the embodiment of the present disclosure, the pressure area of the structure is reduced by having the channels formed on the brazing planes, and through a diagonal arrangement of each the channels. The structure is neither perpendicular nor parallel to the brazing planes, which increases the possibility of gas and flux to be discharged, and reduces the amount of voids being produced during the brazing process, so as to effectively improve the quality of brazing.

Specifically speaking, the channels T can be formed by the manner of being cut out by hand tools, carved out using sandpaper, or cut out using a computer numerical control machine, etc. In order to meet the requirements of rapid production in modern industry, the channels T can be formed in a surface finishing manner by a semi-automatic surface finishing machine. However, if a surface finishing line direction is perpendicular to a certain surface wall, the surface finishing line direction will become parallel to other surface walls, which decreases an effect of air discharge. The channels T are surface finishing line structures formed in diagonal directions using the surface finishing manner, and the surface finishing line structures are formed in a same direction as the diagonal directions to increase the effect of air discharge. In addition, the channels T can also be formed on the second brazing plane 201.

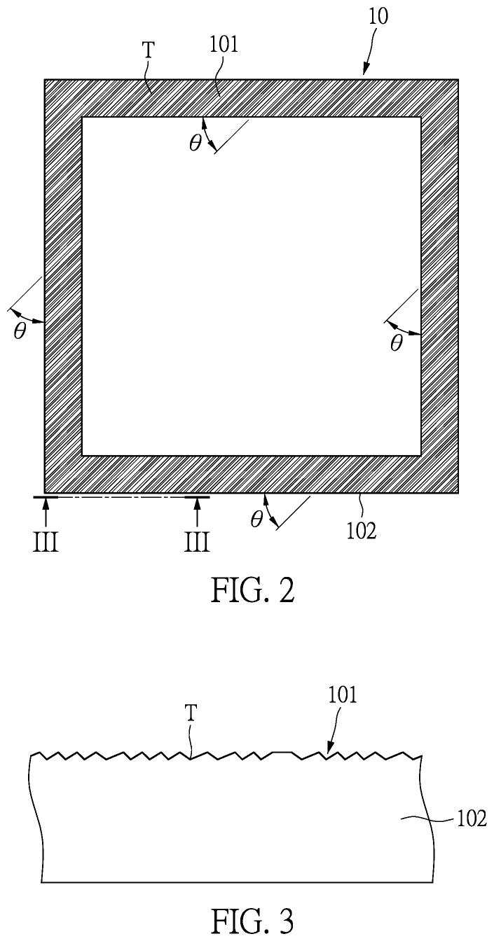

In the present embodiment, the surface finishing line structures formed on the first brazing plane 101 is in an extended diagonal arrangement that has a lower left side and a higher right side (as shown in the directions of FIG. 2), but the surface finishing line structure in the extended diagonal arrangement can also have a higher left side and a lower right side, and it is not limited thereto.

Moreover, the first brazing plane 101 is formed by the top surfaces of four of the surface walls 102, and a surface finishing line angle θ of the surface finishing line structure formed on the first brazing plane 101 is preferably to be 45 degrees to a long side of each of the surface walls 102 (as shown in FIG. 2), so as to increase the effect of air discharge.

In addition, a spacing density of the surface finishing line structure can vary irregularly or regularly when being formed on the first brazing plane 101.

Furthermore, as shown in FIG. 3, in order to achieve a greater air discharging effect, the surface finishing line structure is formed by the channels T on the first brazing plane 101, such that a surface roughness Ra of the first brazing plane 101 is preferably from 3.2 to 6.4 μm, so as to achieve the greater air discharging effect.

In conclusion, the embodiment of the present disclosure provides the enclosed heat sink with the brazed structure to reduce a pressure area of the structure by forming the channels through the brazing planes, and through the diagonal arrangement of each the channels. The structure is neither perpendicular nor parallel to the brazing planes, which increases the possibility of gas and flux to be discharged, and reduces the amount of voids being produced during the brazing process, so as to effectively improve the quality of brazing.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An enclosed heat sink with a brazed structure, comprising:
a first brazing plane formed by a top surface of a first brazing body and a second brazing plane formed by a bottom surface of a second brazing body, the first brazing plane and the second brazing plane being pressed and brazed together, so that the first brazing body and the second brazing body enclose a cavity; wherein a plurality of channels are formed on the first brazing plane, and each of the channels is neither perpendicular nor parallel to the first brazing plane.

2. The enclosed heat sink according to claim 1, wherein a plurality of the channels are also formed on the second brazing plane, and each of the channels on the second brazing plane is neither perpendicular nor parallel to the second brazing plane.

3. The enclosed heat sink according to claim 1, wherein the channels are surface finishing line structures formed in a diagonal direction in a surface finishing manner.

4. The enclosed heat sink according to claim 1, wherein the channels are cut out using hand tools, carved out using sandpaper, or cut out using a computer numerical control machine.

5. The enclosed heat sink according to claim 1, wherein the first brazing body is a box-shaped body, and the second brazing body is a cover body.

6. The enclosed heat sink according to claim 5, wherein the first brazing body has the box-shaped body that is surrounded by a plurality of surface walls, and the first brazing plane is jointly formed by top surfaces of the surface walls.

7. The enclosed heat sink according to claim 6, wherein the channels are surface finishing line structures formed in a diagonal direction in a surface finishing manner, and a surface finishing line angle between the surface finishing structure and a long side of each of the surface walls is 45 degrees.

8. The enclosed heat sink according to claim 2, wherein a surface finishing line structure is formed by the channels, such that a surface roughness Ra of the first brazing plane is from 3.2 to 6.4 μm.
